(19) United States
(12) Patent Application Publication
(10) Pub. No.: US 2025/0323411 A1
(43) Pub. Date: Oct. 16, 2025

(54) DISPLAY DEVICE AND MOBILE ELECTRONIC DEVICE

(71) Applicants: Samsung Display Co., LTD., Yongin-si (KR); UNIST (ULSAN NATIONAL INSTITUTE OF SCIENCE AND TECHNOLOGY), Ulju-gun (KR)

(72) Inventors: Jae Uk CHOI, Yongin-si (KR); Gangil BYUN, Ulju-gun (KR); Ki Seo KIM, Yongin-si (KR); Phuong Linh HOANG, Ulju-gun (KR)

(21) Appl. No.: 19/098,270

(22) Filed: Apr. 2, 2025

(30) Foreign Application Priority Data
Apr. 11, 2024 (KR) 10-2024-0048635
May 20, 2024 (KR) 10-2024-0065072

(51) Int. Cl. H01Q 1/24; H01Q 1/38; H01Q 1/46

(52) U.S. Cl. CPC H01Q 1/243; H01Q 1/38; H01Q 1/46

(57) ABSTRACT

Provided are a display device and a mobile electronic device. The display device includes a display panel including a display area, a non-display area disposed outside the display area and a protrusion area extended from a portion of the non-display area, and a circuit board connected to the protrusion area. The antenna is electrically connected to the circuit board in the protrusion area. The antenna includes a first transmission line portion positioned in the protrusion area, an impedance matching portion disposed in the protrusion area and extended from the first transmission line portion, a second transmission line portion extended from the impedance matching portion and disposed over a first area of the non-display area corresponding to a corner of the display panel from the protrusion area, and a radiation pattern portion extended from the second transmission line portion and disposed in a second area of the non-display area corresponding to a side of the display panel, wherein the radiation pattern portion includes a plurality of radiation slots asymmetrically arranged.

This application claims priority to Korean Patent Application No. 10-2024-0048635, filed on Apr. 11, 2024, and Korean Patent Application No. 10-2024-0065072, filed on May 20, 2024, and all the benefits accruing therefrom under 35 U.S.C. § 119, the contents of which in their entirety are herein incorporated by reference.

### BACKGROUND

### 1. Technical Field

Embodiments of the present disclosure relate to a display device and a mobile electronic device.

### 2. Description of the Related Art

With the advancement of the information age, the demand for display devices of various forms for displaying an image has increased. For example, display devices have been applied to various electronic devices such as, for example, a smart phone, a digital camera, a laptop computer, a navigator and a smart television.

A mobile electronic device may include an antenna for transmitting and receiving electromagnetic waves for wireless communication or various types of sensing. However, with the size reduction of bezel areas of recent mobile electronic devices, changing the design of a space in which the antenna is to be disposed may be desired.

### SUMMARY

Embodiments of the present disclosure provide a display device and a mobile electronic device, in which an antenna for transmitting and receiving electromagnetic waves is embedded in a display panel.

Embodiments of the present disclosure provide a display device and a mobile electronic device, in which an area of an antenna is reduced and the antenna is easily designed to correspond to various types of a display panel.

Embodiments of the present disclosure provide a display device including a display panel including a display area, a non-display area disposed outside the display are, a protrusion area extended from a portion of the non-display area, and an antenna, and a circuit board connected to the protrusion area. The antenna is electrically connected to the circuit board in the protrusion area. The antenna includes a first transmission line portion positioned in the protrusion area, an impedance matching portion disposed in the protrusion area and extended from the first transmission line portion, a second transmission line portion extended from the impedance matching portion and disposed over a first area of the non-display area corresponding to a corner of the display panel from the protrusion area, and a radiation pattern portion extended from the second transmission line portion and disposed in a second area of the non-display area corresponding to a side of the display panel, wherein the radiation pattern portion includes a plurality of radiation slots asymmetrically arranged.

The first transmission line portion may include a first power supply line, a first ground disposed on one side of the first power supply line, and a second ground disposed on another side of the first power supply line.

The impedance matching portion may include a second power supply line extended from the first power supply line and including a plurality of matching slots having different respective areas, a third ground in a form of a quadrant disposed on one side of the second power supply line and extended from the first ground, and a fourth ground in a form of a quadrant disposed on another side of the second power supply line and extended from the second ground.

The third ground and the fourth ground may be symmetrical to each other with respect to the second power supply line.

The plurality of matching slots may include a first matching slot having a first area, a second matching slot disposed adjacent to the first matching slot and having a second area larger than the first area, a third matching slot disposed adjacent to the second matching slot and having a third area larger than the second area, a fourth matching slot disposed adjacent to the third matching slot and having a fourth area larger than the third area, a fifth matching slot disposed adjacent to the fourth matching slot and having a fifth area larger than the fourth area, and a sixth matching slot disposed adjacent to the fifth matching slot and having a sixth area larger than the fifth area.

The second transmission line portion may include a third power supply line extended from the second power supply line, and the third power supply line includes a plurality of slots each having the same area.

A portion of the second transmission line portion may be bent toward a lower portion of the display panel at a boundary area between the protrusion area and the non-display area.

The radiation pattern portion may extend from the third power supply line.

The plurality of radiation slots may include a first slot unit including a first radiation slot, a second radiation slot, a third radiation slot, and a fourth radiation slot having different respective areas, and a second slot unit including a fifth radiation slot, a sixth radiation slot, a seventh radiation slot, and an eighth radiation slot having different respective areas. The first slot unit and the second slot unit may be alternately disposed along a direction in which the second area of the non-display area extends.

An area of the first radiation slot may be larger than an area of the second radiation slot. The area of the second radiation slot may be larger than an area of the third radiation slot. The area of the third radiation slot may be larger than an area of the fourth radiation slot. The area of the fifth radiation slot may be smaller than an area of the sixth radiation slot. The area of the sixth radiation slot may be smaller than an area of the seventh radiation slot. The area of the seventh radiation slot may be smaller than an area of the eighth radiation slot.

Embodiments of the present disclosure provide a display device including a display panel including a display area, a non-display area disposed outside the display area, a protrusion area extended from a portion of the non-display area, and an antenna, and a circuit board connected to the protrusion area. The antenna is electrically connected to the circuit board in the protrusion area. The antenna includes a first transmission line portion positioned in the protrusion area, an impedance matching portion disposed in the protrusion area and extended from the first transmission line portion, a second transmission line portion extended from the impedance matching portion and disposed over a first area of the non-display area corresponding to a corner of the display panel from the protrusion area, and a radiation pattern portion extended from the second transmission line portion and disposed in a second area of the non-display area corresponding to a side of the display panel, wherein the radiation pattern portion includes a plurality of radiation slots asymmetrically arranged.

The first transmission line portion may include a first power supply line, a first ground disposed on one side of the first power supply line, and a second ground disposed on another side of the first power supply line.

The impedance matching portion may include a second power supply line extended from the first power supply line, including a plurality of matching slots having different respective areas, a third ground in a form of a quadrant disposed on one side of the second power supply line and extended from the first ground, and a fourth ground in a form of a quadrant disposed on another side of the second power supply line and extended from the second ground.

The third ground and the fourth ground may be symmetrical to each other with respect to the second power supply line.

The plurality of matching slots may include a first matching slot having a first area, a second matching slot disposed adjacent to the first matching slot and having a second area larger than the first area, a third matching slot disposed adjacent to the second matching slot and having a third area larger than the second area, a fourth matching slot disposed adjacent to the third matching slot and having a fourth area larger than the third area, a fifth matching slot disposed adjacent to the fourth matching slot and having a fifth area larger than the fourth area, and a sixth matching slot disposed adjacent to the fifth matching slot and having a sixth area larger than the fifth area.

The second transmission line portion may include a third power supply line extended from the second power supply line, and the third power supply line includes a plurality of slots each having the same area.

A portion of the second transmission line portion may be bent toward a lower portion of the display panel at a boundary area between the protrusion area and the non-display area.

The radiation pattern portion may extend from the third power supply line.

The plurality of radiation slots may include a first slot unit including a first radiation slot, a second radiation slot, a third radiation slot, and a fourth radiation slot having different respective areas, a second slot unit including a fifth radiation slot, a sixth radiation slot, a seventh radiation slot, and an eighth radiation slot having different respective areas. The first slot unit and the second slot unit may be alternately disposed along a direction in which the second area of the non-display area extends.

An area of the first radiation slot may be larger than an area of the second radiation slot. The area of the second radiation slot may be larger than an area of the third radiation slot. The area of the third radiation slot may be larger than an area of the fourth radiation slot. The area of the fifth radiation slot may be smaller than an area of the sixth radiation slot. The area of the sixth radiation slot may be smaller than an area of the seventh radiation slot. The area of the seventh radiation slot may be smaller than an area of the eighth radiation slot.

In the embodiments according to the present disclosure, an antenna for transmitting and receiving electromagnetic waves may be embedded in a display panel.

In some aspects, in the embodiments according to the present disclosure, the antenna is easily designed to correspond to various types of the display panel.

### BRIEF DESCRIPTION OF THE DRAWINGS

These and/or other features supported by aspects of the present disclosure will become apparent and more readily appreciated from the following description of the embodiments, taken in conjunction with the accompanying drawings, in which:

FIGS. 1 and 2 are plan views illustrating a display device according to an embodiment;

FIGS. 3 and 4 are one side views illustrating a display device according to an embodiment;

FIGS. 5 and 6 are plan views illustrating a display device according to another embodiment;

FIG. 7 is a plan view illustrating an antenna according to an embodiment;

FIG. 8 is a plan view illustrating a first transmission line portion illustrated in FIG. 7;

FIG. 9 is a plan view illustrating an impedance matching portion illustrated in FIG. 7;

FIG. 10 is a plan view illustrating a second transmission line portion illustrated in FIG. 7;

FIG. 11 is a plan view illustrating a radiation pattern portion illustrated in FIG. 7;

FIGS. 12 to 18 are graphs illustrating characteristics of an antenna of FIG. 7 as experimented with respect to various frequencies;

FIG. 19 is a cross-sectional view illustrating a partial layer of a display panel including an antenna illustrated in FIG. 7;

FIG. 20 is a cross-sectional view illustrating a partial layer of a display panel including an antenna according to another embodiment; and

FIG. 21 is a graph illustrating characteristics of the antenna illustrated in FIG. 7 compared with characteristics of the antenna illustrated in FIG. 20.

### DETAILED DESCRIPTION OF THE DISCLOSURE

Embodiments of the present disclosure will now be described more fully hereinafter with reference to the accompanying drawings, in which example embodiments of the present disclosure are illustrated. Aspects of the present disclosure may, however, be embodied in different forms and should not be construed as limited to the embodiments set forth herein. Rather, the example embodiments are provided such that this disclosure will be thorough and complete, and will fully convey the scope of example aspects of the present disclosure to those skilled in the art. The same reference numbers indicate the same components throughout the specification. In the attached drawing figures, the thickness of layers and regions is exaggerated for clarity.

It will be understood that, although the terms “first,” “second,” “third,” and the like may be used herein to describe various elements, components, regions, layers and/or sections, these elements, components, regions, layers and/or sections should not be limited by these terms. These terms are used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will also be understood that when a layer is referred to as being “on” another layer or substrate, it can be directly on the other layer or substrate, or intervening layers may also be present. In contrast, when an element is referred to as being “directly on” another element, there are no intervening elements present.

The terminology used herein is for the purpose of describing particular example embodiments and is not intended to be limiting. As used herein, the singular forms “a,” “an,” and “the” are intended to include the plural forms, including “at least one,” unless the content clearly indicates otherwise. “Or” means “and/or.” “At least one of A and B” means “A and/or B.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

In some embodiments, descriptions of an element being “adjacent” to another element as used herein may refer to the element being relatively close to or near to the other element, for example, with a certain spacing between the elements.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments of the present disclosure will be described in detail with reference to the accompanying drawings.

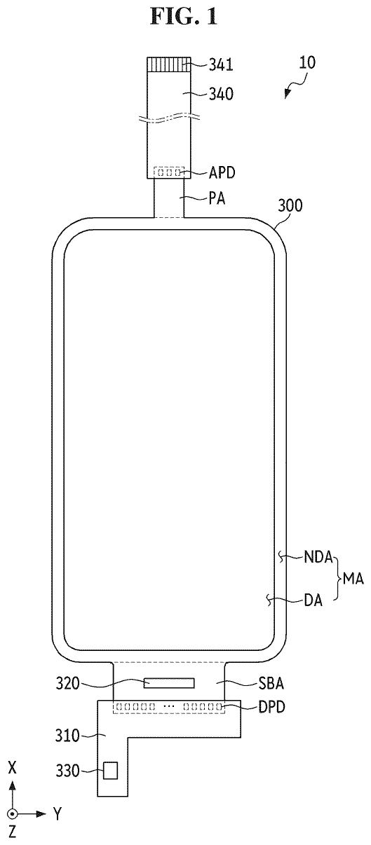

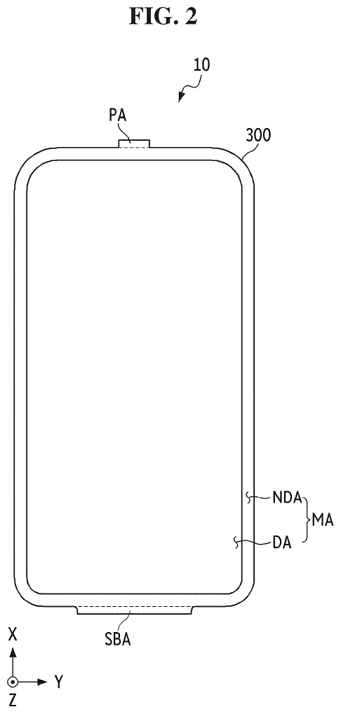

FIGS. 1 and 2 are plan views illustrating a display device according to an embodiment.

Referring to FIGS. 1 and 2, a display device 10 according to an embodiment may be applied to a mobile electronic device such as, for example, a mobile phone, a smart phone, a tablet personal computer (PC), a mobile communication terminal, an electronic diary, an electronic book, a portable multimedia player (PMP), a navigator and an ultra mobile PC (UMPC). In some cases, the display device 10 according to an embodiment may be applied to a television, a laptop computer, a monitor, a signboard or a display unit of Internet of things (IoT). In some cases, the display device 10 according to an embodiment may be applied to a wearable device such as, for example, a smart watch, a watch phone, an eyeglasses-type display and a head mounted display (HMD).In some cases, the display device 10 according to an embodiment may be applied to a center information display (CID) disposed in a dashboard of a vehicle, a room mirror display that replaces a side mirror of a vehicle or a display disposed on a rear surface of a front seat as an entertainment for a rear seat of a vehicle.

In the present disclosure, a first direction (X-axis direction) is a short side direction of the display device 10, and may be, for example, a vertical direction of the display device 10. A second direction (Y-axis direction) is a long side direction of the display device 10, and may be, for example, a horizontal direction of the display device 10. A third direction (Z-axis direction) may be a thickness direction of the display device 10. A corner where the long side in the first direction (X-axis direction) and the short side in the second direction (Y-axis direction) meet may be rounded to have a predetermined curvature or formed at a right angle.

The display device 10 according to an embodiment includes a display panel 300, a display circuit board 310, a display driving circuit 320, a touch driving circuit 330 and an antenna circuit board 340. A connector 341 may be formed on one side of the antenna circuit board 340.

The display panel 300 may be a light emitting display panel including a light emitting element. For example, the display panel 300 may be an organic light emitting display panel using an organic light emitting diode including an organic light emitting layer, a micro light emitting diode display panel using a micro LED, a quantum dot light emitting display panel using a quantum dot light emitting diode including a quantum dot light emitting layer or an inorganic light emitting display panel using an inorganic light emitting element including an inorganic semiconductor.

The display panel 300 may be a flexible display panel that is flexible and thus may be easily bent, folded or rolled. For example, the display panel 300 may be a foldable display panel that may be folded and unfolded, a curved display panel of which display surface is curved, a bended display panel in which an area other than the display surface is bent, a rollable display panel that may be rolled or unrolled or a stretchable display panel that may be elongated.

The display panel 300 may include a main area MA, a sub-area SBA protruded from one side of the main area MA and a protrusion area PA protruded from another side of the main area MA.

The main area MA may include a display area DA for displaying an image and a non-display area NDA that is a peripheral area of the display area DA. The display area DA may occupy most of the main area MA. The display area DA may be disposed at the center of the main area MA. The non-display area NDA may be an outer area of the display area DA. The non-display area NDA may be defined as an edge area of the display panel 300. The non-display area NDA may be referred to as a “dead space area”.

The sub-area SBA may protrude from one side of the main area MA in the first direction (X-axis direction). For example, one side of the main area MA may be a lower side of the main area MA. As illustrated in FIG. 1, a length of the sub-area SBA in the first direction (X-axis direction) may be shorter than a length of the main area MA in the first direction (X-axis direction), and a length of the sub-area SBA in the second direction (Y-axis direction) may be shorter than a length of the main area MA in the second direction (Y-axis direction), but embodiments of the present disclosure are not limited thereto.

Referring to FIG. 2, the sub-area SBA may be bent, and at least a portion of the bent sub-area SBA may be disposed below the display panel 300. In this case, at least a portion of the sub-area SBA may overlap the main area MA of the display panel 300 in the third direction (Z-axis direction).

Display pads DPD may be disposed at one edge of the sub-area SBA. One edge of the sub-area SBA may be a lower edge of the sub-area SBA. The display circuit board 310 may be attached onto the display pads DPD of the sub-area SBA. The display circuit board 310 may be attached to the display pads DPD of the sub-area SBA by using a conductive adhesive member such as, for example, an anisotropic conductive film and an anisotropic conductive paste. The display circuit board 310 may be a flexible printed circuit board (FPCB) that may be bent, a rigid printed circuit board (PCB) that is rigid and not easily bent or a composite printed circuit board that includes both a rigid printed circuit board and a flexible printed circuit board.

The display driving circuit 320 may be disposed on the sub-area SBA of the display panel 300. The display driving circuit 320 may receive control signals and power voltages and generate and output signals and voltages for driving the display panel 300. The display driving circuit 320 may be formed of an integrated circuit (IC).

The touch driving circuit 330 may be disposed on the display circuit board 310. The touch driving circuit 330 may be formed of an integrated circuit. The touch driving circuit 330 may be attached to the display circuit board 310.

The touch driving circuit 330 may be electrically connected to sensor electrodes of the sensor electrode layer of the display panel 300 through the display circuit board 310. The touch driving circuit 330 may output a touch driving signal to each of the sensor electrodes and detect a voltage change according to mutual capacitance of the sensor electrodes.

The sensor electrode layer of the display panel 300 may sense a proximity touch and/or a contact touch. The contact touch means that an object, such as, for example, a person's finger or pen, comes into direct contact with a cover window disposed on the sensor electrode layer. The proximity touch means that an object, such as, for example, a person's finger or pen, is positioned over the cover widow to be a little spaced apart from the cover window, like hovering.

Display pixels of the display panel 300 and a power supply unit for supplying driving voltages for driving the display driving circuit 320 may be additionally disposed on the display circuit board 310. Alternatively, the power supply unit may be integrated with the display driving circuit 320, and in this case, the display driving circuit 320 and the power supply unit may be formed as one integrated circuit.

The protrusion area PA may be an area that includes at least one element of a power supply line, a ground line or an antenna electrode of an antenna module for wireless communication. The protrusion area PA may protrude from another side of the main area MA in the first direction (X-axis direction). The protrusion area PA may protrude from a portion of the non-display area NDA in the first direction (X-axis direction). For example, the other side of the main area MA may be an upper side of the main area MA. As illustrated in FIG. 1, a length of the protrusion area PA in the first direction (X-axis direction) may be shorter than a length of the main area MA in the first direction (X-axis direction) and a length of the protrusion area PA in the second direction (Y-axis direction) may be shorter than a length of the main area MA in the second direction (Y-axis direction), but embodiments of the present disclosure are not limited thereto.

As illustrated in FIG. 2, at least a portion of the protrusion area PA may be bent, and at least a portion of the bent protrusion area PA may be disposed below the display panel 300. In this case, at least a portion of the protrusion area PA may overlap the main area MA of the display panel 300 in the third direction (Z-axis direction).

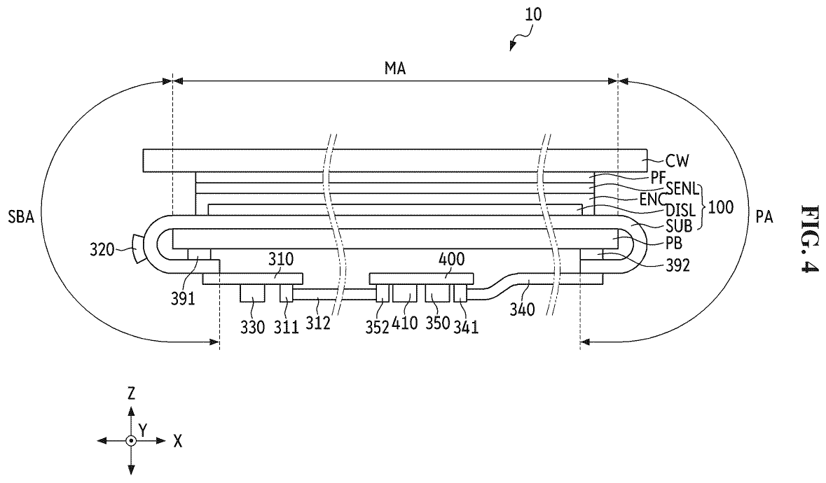

Antenna pads APD may be disposed at one edge of the protrusion area PA. The antenna circuit board 340 may be attached onto the antenna pads APD of the protrusion area PA. The antenna circuit board 340 may be attached onto the antenna pads APD of the protrusion area PA by using a conductive adhesive member such as, for example, an anisotropic conductive film and an anisotropic conductive adhesive. One side of the antenna circuit board 340 may include a connector 341 connected to a main circuit board 400 on which an antenna driving circuit (350 of FIG. 4) is packaged. The antenna circuit board 340 may be a flexible printed circuit board (FPCB) that may be bent.

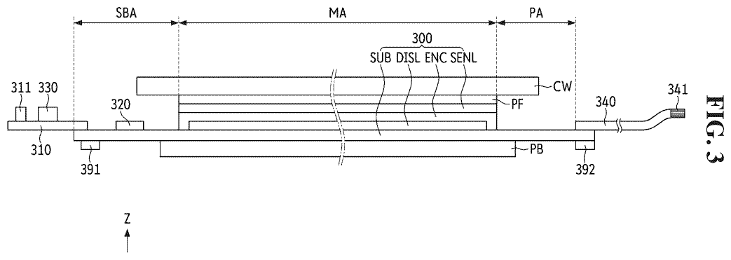

FIGS. 3 and 4 are side views illustrating a display device according to an embodiment.

Referring to FIGS. 3 and 4, the display device 10 according to an embodiment may include a display panel 300, a polarizing film PF, a cover window CW and a panel lower cover PB. The display panel 300 may include a substrate SUB, a display layer DISL, an encapsulation layer ENC and a sensor electrode layer SENL.

The substrate SUB may be formed of an insulating material such as, for example, a polymer resin. The substrate SUB may be a flexible substrate capable of being subjected to bending, folding, rolling or the like.

In the main area MA, the display layer DISL may be disposed on the substrate SUB. The display layer DISL may be a layer that includes light emission areas to display an image. The display layer DISL may include a thin film transistor layer on which thin film transistors are formed, and a light emitting element layer in which light emitting elements for emitting light are disposed in the light emission areas.

Scan lines, data lines, power lines, and the like for driving the light emitting elements of the light emission area may be disposed in the display area DA of the display layer DISL. A scan driver for outputting scan signals to the scan lines and fan-out lines connecting the data lines with the display driving circuit 320 may be disposed in the non-display area NDA of the display layer DISL.

The encapsulation layer ENC may be disposed on the display layer DISL. The encapsulation layer ENC may be a layer which encapsulates the light emitting element layer of the display layer DISL and prevents oxygen or moisture from being permeated into the light emitting element layer of the display layer DISL. The encapsulation layer ENC may be disposed on an upper surface and sides of the display layer DISL.

The sensor electrode layer SENL may be disposed on the display layer DISL. The sensor electrode layer SENL may include sensor electrodes. The sensor electrode layer SENL may sense a touch by using the sensor electrodes.

The polarizing film PF may be disposed on the sensor electrode layer SENL. The polarizing film PF may include a first base member, a linear polarizing plate, a phase delay film such as, for example, a λ/4 plate (quarter-wave plate), and a second base member. The first base member, the phase delay film, the linear polarizing plate and the second base member may be sequentially stacked on the sensor electrode layer SENL.

The cover window CW may be disposed on the polarizing film PF. The cover window CW may be attached onto the polarizing film PF by a transparent adhesive member such as, for example, an optically clear adhesive (OCA) film.

The panel lower cover PB may be disposed below the display panel 300. The panel lower cover PB may be attached to a lower surface of the display panel 300 through an adhesive member. The adhesive member may be a pressure sensitive adhesive (PSA). The panel lower cover PB may include at least one of a light blocking member for absorbing light incident from the outside, a buffer member for absorbing an impact from the outside, or a heat dissipation member for efficiently discharging heat of the display panel 300.

The light blocking member may be disposed below the display panel 300. The light blocking member blocks transmission of light and may prevent components disposed below the light blocking member, for example, the display circuit board 310, and the like from being viewed from an upper portion of the display panel 300. The light blocking member may include a light absorbing material such as, for example, a black pigment or a black dye.

The buffer member may be disposed below the light blocking member. The buffer member absorbs external impacts and may prevent the display panel 300 from being damaged. The buffer member may include a single layer or a plurality of layers. For example, the buffer member may be formed of a polymer resin such as, for example, polyurethane, polycarbonate, polypropylene and polyethylene, or may include a material having elasticity such as, for example, a sponge formed by foaming a rubber, a urethane-based material or an acrylic-based material.

The heat dissipation member may be disposed below the buffer member. The heat dissipation member may include a first heat dissipation layer including graphite or carbon nanotubes and a second heat dissipation layer formed of a metal thin film such as, for example, copper, nickel, ferrite or silver, which may shield electromagnetic waves and have excellent thermal conductivity.

According to an embodiment, as illustrated in FIG. 4, the substrate SUB may be bent in the sub-area SBA, and may be disposed below the display panel 300. The sub-area SBA of the substrate SUB may be attached to a lower surface of the panel lower cover PB by a first adhesive member 391. The first adhesive member 391 may be a pressure sensitive adhesive.

According to an embodiment, as illustrated in FIG. 4, the protrusion area PA of the substrate SUB may be bent, and may be disposed below the display panel 300. The protrusion area PA of the substrate SUB may be attached to the lower surface of the panel lower cover PB by a second adhesive member 392. The second adhesive member 392 may be a pressure sensitive adhesive.

The display circuit board 310 may be attached to the display pads DPD of the sub-area SBA of the substrate SUB by using a conductive adhesive member such as, for example, an anisotropic conductive film and an anisotropic conductive adhesive. The display circuit board 310 may include a connector 311 connected to the flexible circuit board 312. The display circuit board 310 may be connected to a connector 352 of the main circuit board 400 by the flexible circuit board 312.

The touch driving circuit 330 may be disposed on the display circuit board 310. The touch driving circuit 330 may generate touch data in accordance with a change in an electrical signal sensed in each of the sensor electrodes of the sensor electrode layer of the display panel 300 and transmit the touch data to a main processor 410 of the main circuit board 400, and the main processor 410 may calculate touch coordinates, in which the touch has occurred, by analyzing the touch data.

The antenna circuit board 340 may be attached to the antenna pads APD of the protrusion area PA of the substrate SUB by using a conductive adhesive member such as, for example, an anisotropic conductive film and an anisotropic conductive adhesive. The connector 351 of the antenna circuit board 340 may be connected to the connector 351 of the main circuit board 400. The protrusion area PA may be connected to the main circuit board 400 by the antenna circuit board 340.

The main circuit board 400 may be a rigid printed circuit board (PCB) that is rigid and not easily bent. The main processor 410 and the antenna driving circuit 350 may be disposed on the main circuit board 400.

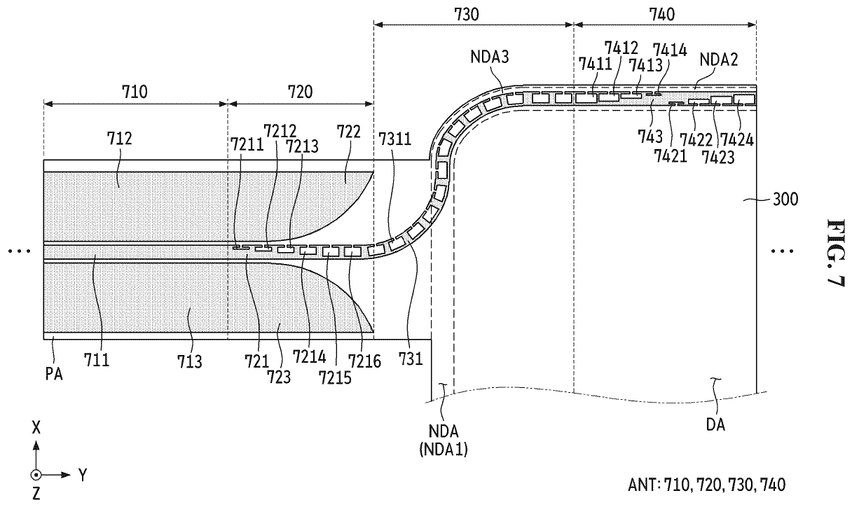

The antenna driving circuit 350 may be electrically connected to an antenna (e.g., ANT of FIG. 7) of the display panel 300 through the antenna circuit board 340. Therefore, the antenna circuit board 340 may be formed of an integrated circuit (IC).

The antenna driving circuit 350 may perform wireless communication by processing electromagnetic wave signals transmitted and received through the antenna ANT. The antenna driving circuit 350 may recognize a gesture of a user's hand by processing the electromagnetic wave signals transmitted and received through the antenna ANT. The antenna driving circuit 350 may detect biometric information such as, for example, the user's breathing and heart rate by processing the electromagnetic wave signals transmitted and received through the antenna ANT.

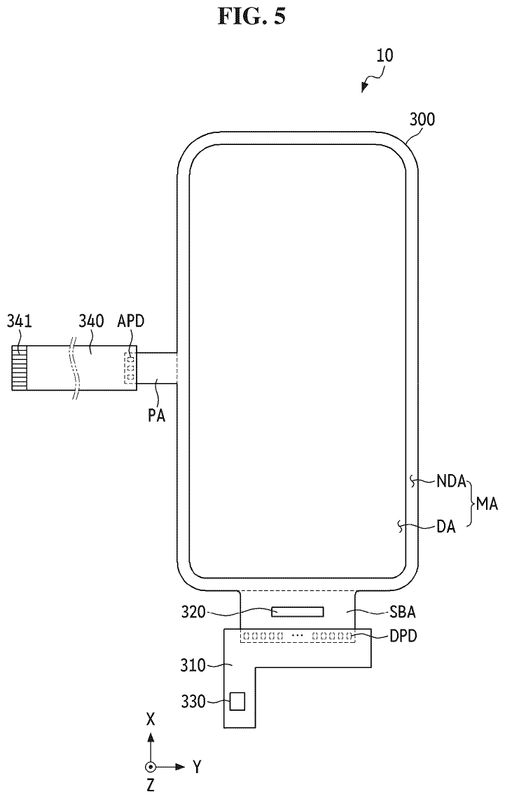

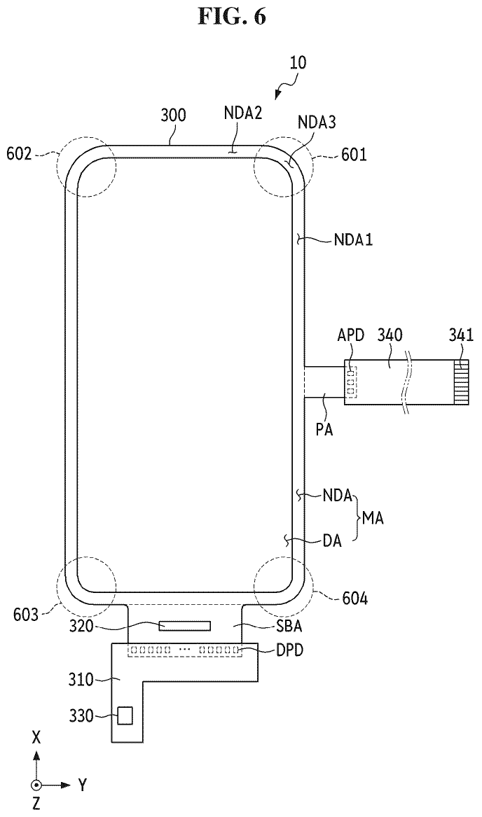

FIG. 5 is a plan view illustrating a display device according to another embodiment. FIG. 6 is a plan view illustrating a display device according to another embodiment.

The embodiment of FIG. 5 is different from the embodiment of FIGS. 1 and 2 in that the protrusion area PA is protruded from a left side of the main area MA in the second direction (Y-axis direction). The embodiment of FIG. 6 is different from the embodiment of FIGS. 1 and 2 in that the protrusion area PA is protruded from a right side of the main area MA in the second direction (Y-axis direction). A redundant description of the embodiments of FIGS. 1 and 2 will be omitted in FIGS. 5 and 6.

As illustrated in FIGS. 5 and 6, the protrusion area PA may protrude from one side of the main area MA, and one side of the main area MA may be any one of an upper side, a lower side, a left side and a right side of the main area MA.

Although not illustrated, the protrusion area PA may protrude from the lower side of the main area MA in the second direction (Y-axis direction), and may be disposed to be spaced apart from the sub-area SBA in the second direction (Y-axis direction). In this case, the length of the protrusion area PA in the first direction (X-axis direction) may be shorter than the length of the sub-area SBA in the first direction (X-axis direction) and the length of the protrusion area PA in the second direction (Y-axis direction) may be shorter than the length of the sub-area SBA in the second direction (Y-axis direction), but embodiments of the present disclosure are not limited thereto.

Referring to FIG. 6, the non-display area includes a first non-display area NDA1 disposed to correspond to a long side of the display panel 300, a second non-display area NDA2 disposed to correspond to a short side of the display panel 300, and a third non-display area NDA3 disposed to correspond to each of corners 601, 602, 603 and 604 of the display panel 300.

According to an embodiment, the corners 601, 602, 603 and 604 of the display panel 300 in which the third non-display area NDA3 is disposed may be designed to have a designated curvature, and the curvature may be variously changed.

According to an embodiment, the display panel 300 includes an antenna (ANT of FIG. 7) that includes a transmission line extended from the protrusion area PA to the third non-display area NDA3. The transmission line of the antenna ANT is configured to facilitate a design change even though the curvature of the third non-display area NDA3 is variously changed. To this end, the antenna ANT according to an embodiment may have a structure as illustrated in FIGS. 7 to 11.

FIG. 7 is a plan view illustrating an antenna according to an embodiment.

Referring to FIG. 7, the antenna ANT according to an embodiment is an antenna ANT of a spoof surface plasmon polaritons structure (hereinafter, referred to as “SSPPs structure”).

Radiation may occur at the antenna ANT of the SSPPs structure due to energy waves which move from a side of the antenna ANT adjacent to a port (e.g., a power supply portion) toward another side (e.g., an opposite side) of the antenna ANT. For example, the antenna ANT of the SSPPs structure may be a leaky wave antenna LWA in which radiation occurs due to energy waves which move from one side to the other side.

According to an embodiment, the antenna ANT may have a specific arrangement structure such that impedance is modulated along a length direction in which the antenna ANT extends. The antenna ANT according to an embodiment is the antenna ANT of the SSPPs structure, and the energy radiated from the antenna ANT may be changed by using characteristics of impedance being modulated.

According to an embodiment, the antenna ANT is divided into four areas. The antenna ANT includes a first transmission line portion 710, an impedance matching portion 720, a second transmission line portion 730, and a radiation pattern portion 740.

The first transmission line portion 710 is disposed in the protrusion area PA. The first transmission line portion 710 may be electrically connected to the antenna circuit board (340 of FIG. 1) through the antenna pad (APD of FIG. 1). The first transmission line portion 710 may be a coplanar waveguide (CPW) transmission line designed for impedance 50 Ω. For example, in some embodiments, the impedance of the first transmission line portion 710 may be 50 Ω.

The impedance matching portion 720 extends from the first transmission line portion 710. The impedance matching portion 720 serves to match the impedance of the antenna ANT.

The second transmission line portion 730 extends from the impedance matching portion 720. The second transmission line portion 730 is disposed over a first area of the non-display area NDA corresponding to a corner (e.g., any one corner 601, 602, 603 or 604) of the display panel 300 extended from the protrusion area PA. The second transmission line portion 730 serves to connect the impedance matching portion 720 with the radiation pattern portion 740. In this case, the first area of the non-display area NDA means the third non-display area NDA3 illustrated in FIG. 6. For example, the first area of the non-display area NDA may correspond to a corner (e.g., any one of the corners 601, 602, 603 and 604) of the display panel 300 illustrated in FIG. 6.

The radiation pattern portion 740 extends from the second transmission line portion 730. The radiation pattern portion 740 is disposed in a second area of the non-display area NDA corresponding to a side (e.g., any one side) of the display panel 300. In this case, the second area of the non-display area NDA means the second non-display area NDA2 illustrated in FIG. 6. For example, the second area of the non-display area NDA may correspond to the short side of the display panel 300, but embodiments of the present disclosure are not limited thereto.

The radiation pattern portion 740 includes a plurality of radiation slots 7411, 7412, 7413, 7414, 7421, 7422, 7423 and 7424 asymmetrically arranged (i.e., arranged in the form of an asymmetry). According to an embodiment, the radiation pattern portion 740 includes a plurality of radiation slots 7411, 7412, 7413, 7414, 7421, 7422, 7423 and 7424 asymmetrically arranged, such that a design width of the antenna ANT may be designed to be less than about 300 mm, and an open stop band effect may be prevented.

The open stop band effect means a phenomenon in which gain of the antenna ANT is significantly reduced in the frequency range of a specific band among broadband frequencies.

The antenna ANT according to an embodiment of the present disclosure includes a plurality of radiation slots 7411, 7412, 7413, 7414, 7421, 7422, 7423 and 7424 having periodicity, wherein the plurality of radiation slots 7411, 7412, 7413, 7414, 7421, 7422, 7423 and 7424 are asymmetrically arranged, such that the open stop band effect may be prevented.

Therefore, the antenna ANT according to an embodiment of the present disclosure may prevent significant reductions in gain in the frequency range of a specific band among broadband frequencies, and may stably operate in the entire broadband frequency range. For example, the antenna ANT according to an embodiment may operate stably in the range of about 45 GHz to about 70 GHz.

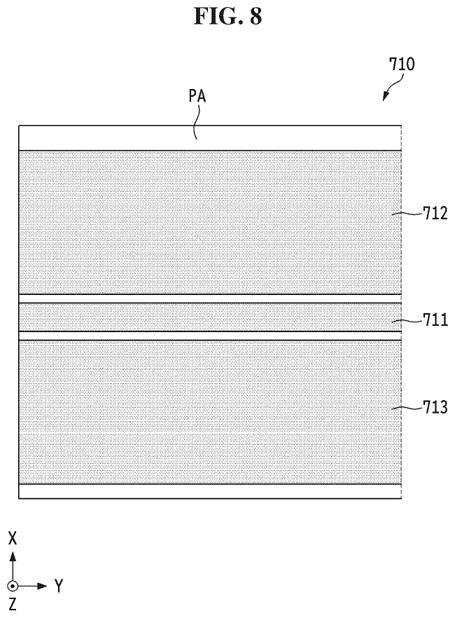

FIG. 8 is a plan view illustrating a first transmission line portion illustrated in FIG. 7.

Referring to FIGS. 7 and 8, the first transmission line portion 710 is disposed in the protrusion area PA.

The first transmission line portion 710 includes a first power supply line 711, a first ground 712 disposed on one side of the first power supply line 711, and a second ground 713 disposed on the other side of the first power supply line 711.

The first power supply line 711 may be electrically connected to the antenna circuit board (340 of FIG. 1) through the antenna pad (APD of FIG. 1). The first ground 712 and the second ground 713 may be disposed on both sides of the first power supply line 711, respectively.

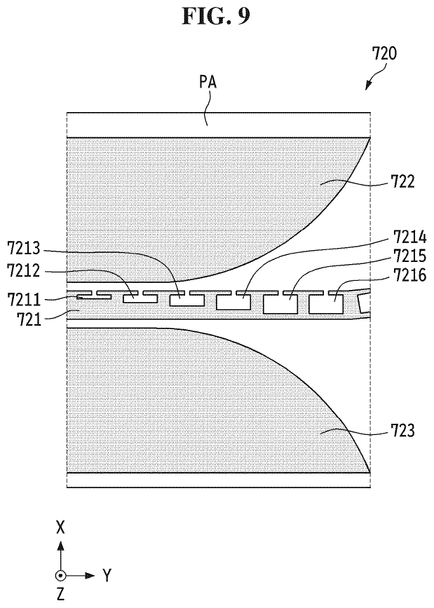

FIG. 9 is a plan view illustrating an impedance matching portion illustrated in FIG. 7.

Referring to FIGS. 7 and 9, the impedance matching portion 720 extends from the first transmission line portion 710, and is disposed in the protrusion area PA.

The impedance matching portion 720 includes a second power supply line 721 extended from the first power supply line 711, a third ground 722 in the form of a quadrant disposed on one side of the second power supply line 721 extended from the first ground 712, and a fourth ground 723 in the form of a quadrant disposed on the other side of the second power supply line 721 extended from the second ground 713. The second power supply line 721 includes a plurality of matching slots 7211, 7212, 7213, 7214, 7215 and 7216 having different respective areas.

In some embodiments, the third ground 722 and the fourth ground 723 may be symmetrical to each other with respect to the second power supply line 721.

The impedance matching portion 720 includes a plurality of matching slots 7211, 7212, 7213, 7214, 7215 and 7216 in the form of a rectangle for frequency modulation. The plurality of matching slots 7211, 7212, 7213, 7214, 7215 and 7216 may have different areas as their heights are adjusted.

The impedance matching portion 720 has a structure which gradually modulates the impedance by gradually increasing or decreasing the heights (i.e., the areas) of the matching slots 7211, 7212, 7213, 7214, 7215 and 7216.

According to an embodiment, the plurality of matching slots 7211, 7212, 7213, 7214, 7215 and 7216 include a first matching slot 7211 having a first area, a second matching slot 7212 disposed adjacent to the first matching slot 7211 and having a second area larger than the first area, a third matching slot 7213 disposed adjacent to the second matching slot 7212 and having a third area larger than the second area, a fourth matching slot 7214 disposed adjacent to the third matching slot 7213 and having a fourth area larger than the third area, a fifth matching slot 7215 disposed adjacent to the fourth matching slot 7214 and having a fifth area larger than the fourth area, and a sixth matching slot 7216 disposed adjacent to the fifth matching slot 7215 and having a sixth area larger than the fifth area.

According to an embodiment, the plurality of matching slots 7211, 7212, 7213, 7214, 7215 and 7216 include the first matching slot 7211 having a first height, the second matching slot 7212 disposed adjacent to the first matching slot 7211 and having a second height greater than the first height, the third matching slot 7213 disposed adjacent to the second matching slot 7212 and having a third height greater than the second height, the fourth matching slot 7214 disposed adjacent to the third matching slot 7214 and having a fourth height greater than the third height, the fifth matching slot 7215 disposed adjacent to the fourth matching slot 7214 and having a fifth height greater than the fourth height, and the sixth matching slot 7216 disposed adjacent to the fifth matching slot 7215 and having a sixth height greater than the fifth height.

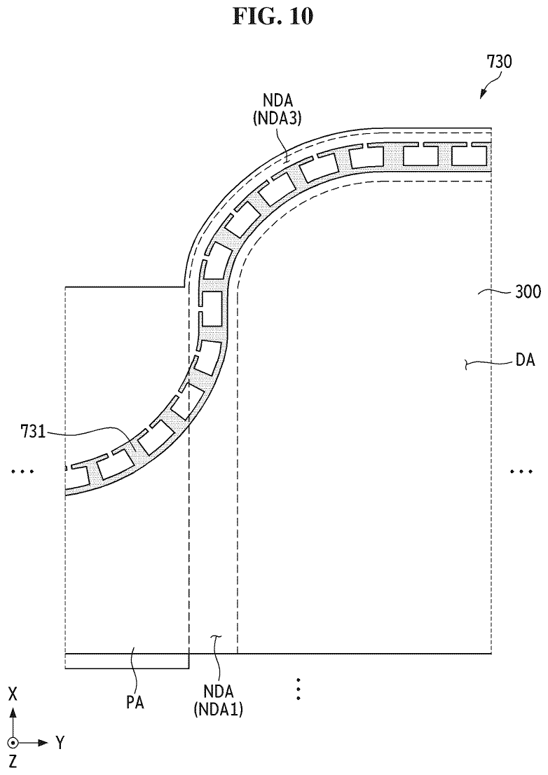

FIG. 10 is a plan view illustrating a second transmission line portion illustrated in FIG. 7.

Referring to FIGS. 7 and 10, the second transmission line portion 730 includes a third power supply line 731 extended from the second power supply line 721, and the third power supply line 731 includes a plurality of slots 7311 each having the same area. For example, each of the plurality of slots 7311 may be designed to have a specific area, for example, a first area.

According to an embodiment, the second transmission line portion 730 may be a “curved SSPPs waveguide” configured or formed by continuously connecting 15 slots of the same SSPPs structure. For example, the second transmission line portion 730 is disposed over the first area of the non-display area NDA corresponding to a corner (e.g., any one corner 601, 602, 603 or 604) of the display panel 300 from the protrusion area PA. Therefore, a portion of the second transmission line portion 730 may be disposed in the form of a curve in the first area of the non-display area NDA corresponding to a corner (e.g., any one corner 601, 602, 603 or 604) of the display panel 300.

According to an embodiment, another portion of the second transmission line portion 730 is bent (e.g., in the negative X-axis direction) toward a lower portion of the display panel 300 at a boundary area between the protrusion area PA and the non-display area NDA. Therefore, another portion of the second transmission line portion 730 may be disposed below the display panel 300 together with the protrusion area PA.

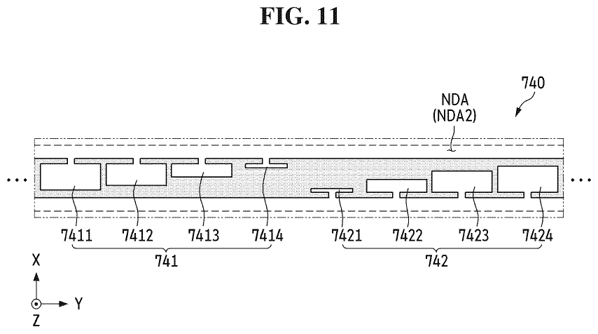

FIG. 11 is a plan view illustrating a radiation pattern portion illustrated in FIG. 7.

Referring to FIGS. 7 and 11, the radiation pattern portion 740 is disposed in the second area (e.g., NDA2 of FIG. 6) of the non-display area NDA corresponding to a side (e.g., any one side) of the display panel 300.

The radiation pattern portion 740 extends from the third power supply line (731 of FIG. 7) of the second transmission line portion (730 of FIG. 7).

The radiation pattern portion 740 includes a plurality of radiation slots 7411, 7412, 7413, 7414, 7421, 7422, 7422 and 7424, which are divided into a first slot unit 741 and a second slot unit 742.

The first slot unit 741 and the second slot unit 742, which are disposed adjacent to each other, constitute one radiator unit, and are disposed to be periodically repeated along a length direction in which the radiation pattern portion 740 extends.

The first slot unit 741 and the second slot unit 742 are disposed in the form of an inverted shape, for example, in a flipped shape. In this way, the antenna ANT according to an embodiment may prevent the open stop band effect by allowing the plurality of radiation slots 7411, 7412, 7413, 7414, 7421, 7422, 7423 and 7424 to be asymmetrically arranged in the radiation pattern portion 740. Expressed another way, the asymmetrical arrangement of the plurality of radiation slots 7411, 7412, 7413, 7414, 7421, 7422, 7423 and 7424 in the radiation pattern portion 740 as described herein may reduce or prevent the open stop band effect.

The first slot unit 741 includes a first radiation slot 7411, a second radiation slot 7412, a third radiation slot 7413 and a fourth radiation slot 7414, which have different areas.

The second slot unit 742 includes a fifth radiation slot 7421, a sixth radiation slot 7422, a seventh radiation slot 7423 and an eighth radiation slot 7424, which have different areas.

The first slot unit 741 and the second slot unit 742 are alternately disposed along a direction in which the second area of the non-display area NDA extends.

The area of the first radiation slot 7411 may be larger than the area of the second radiation slot 7412, the area of the second radiation slot 7412 may be larger than the area of the third radiation slot 7413, and the area of the third radiation slot 7413 may be larger than the area of the fourth radiation slot 7414.

The area of the fifth radiation slot 7421 may be smaller than the area of the sixth radiation slot 7422, the area of the sixth radiation slot 7422 may be smaller than the area of the seventh radiation slot 7423, and the area of the seventh radiation slot 7423 may be smaller than the area of the eighth radiation slot 7424.

The height of the first radiation slot 7411 may be greater than the height of the second radiation slot 7412, the height of the second radiation slot 7412 may be greater than the height of the third radiation slot 7413, and the height of the third radiation slot 7413 may be greater than the height of the fourth radiation slot 7414.

The height of the fifth radiation slot 7421 may be smaller than the height of the sixth radiation slot 7422, the height of the sixth radiation slot 7422 may be smaller than the height of the seventh radiation slot 7423, and the height of the seventh radiation slot 7423 may be smaller than the height of the eighth radiation slot 7424.

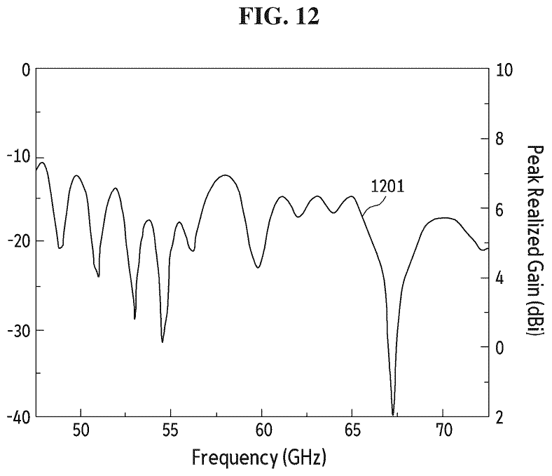

FIGS. 12 to 18 are graphs illustrating characteristics of an antenna of FIG. 7 experimented with respect to various frequencies.

FIG. 12 is a graph illustrating gain for each frequency of the antenna ANT of FIG. 7 as experimented.

A curve 1201 illustrated in FIG. 12 is an S parameter curve in which the amount of radiated energy returning to a first port disposed on one side of the antenna ANT through reflection is experimented when the energy is radiated from the first port through the antenna ANT.

The curve 1201 illustrated in FIG. 12 means that the smaller its value is, the better performance of the antenna ANT is. It is noted that the curve has a value of about −10 dB or less in the entire range of about 45 GHz to 70 GHz. Therefore, it is noted from the antenna ANT according to an embodiment illustrated in FIG. 7 that a phenomenon (i.e., the open stop band effect), in which gain of the antenna ANT is significantly reduced in the frequency range of a specific band, is reduced.

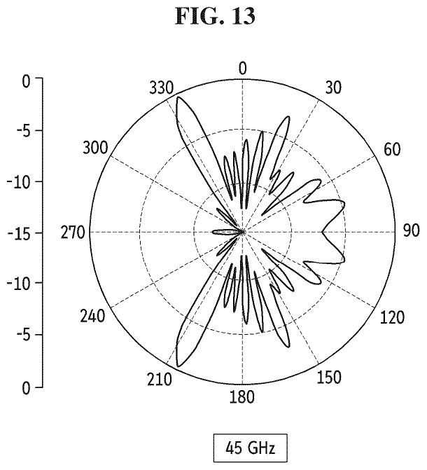

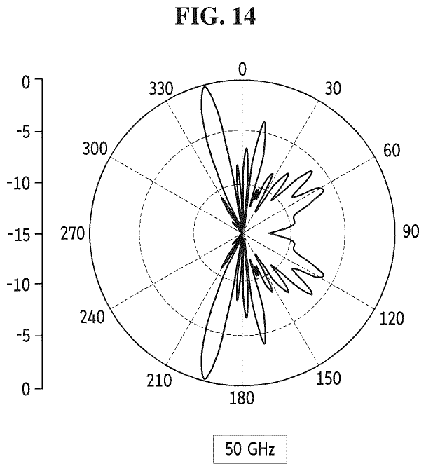

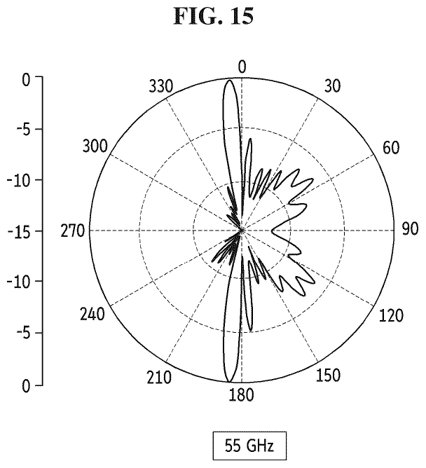

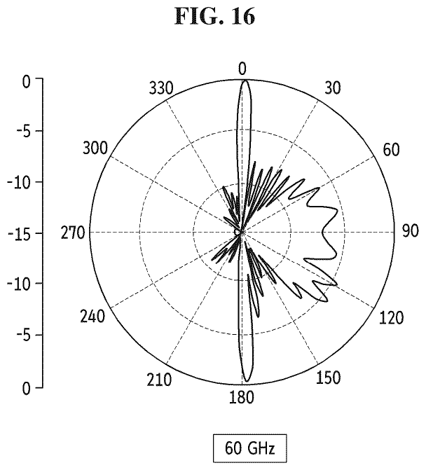

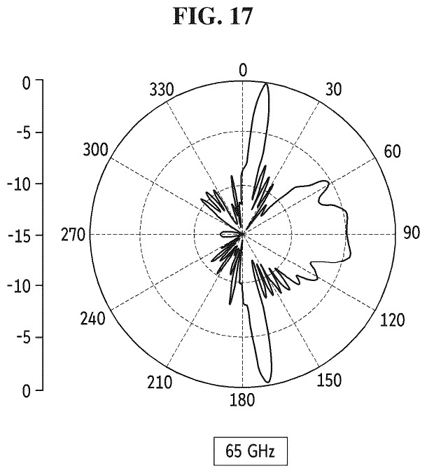

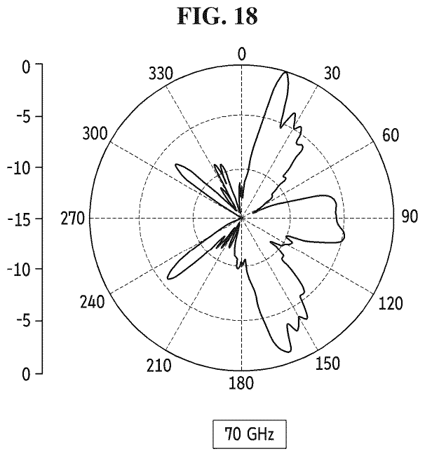

FIG. 13 is a graph illustrating radiation characteristics of an antenna according to an embodiment experimented at a frequency of about 45 GHz. FIG. 14 is a graph illustrating radiation characteristics of an antenna according to an embodiment experimented at a frequency of about 50 GHz. FIG. 15 is a graph illustrating radiation characteristics of an antenna according to an embodiment experimented at a frequency of about 55 GHz. FIG. 16 is a graph illustrating radiation characteristics of an antenna according to an embodiment experimented at a frequency of about 60 GHz. FIG. 17 is a graph illustrating radiation characteristics of an antenna according to an embodiment experimented at a frequency of about 65 GHz. FIG. 18 is a graph illustrating radiation characteristics of an antenna according to an embodiment experimented at a frequency of about 70 GHz.

Referring to FIGS. 13 to 18, it is noted that the antenna ANT according to an embodiment may be designed at various radiation angles as its frequency is modulated. For example, it is noted from the antenna ANT according to an embodiment that a radiation angle of the antenna is changed in conjunction with varying the frequency in the range of about 45 GHz to about 70 GHz, as illustrated in FIGS. 13 to 18.

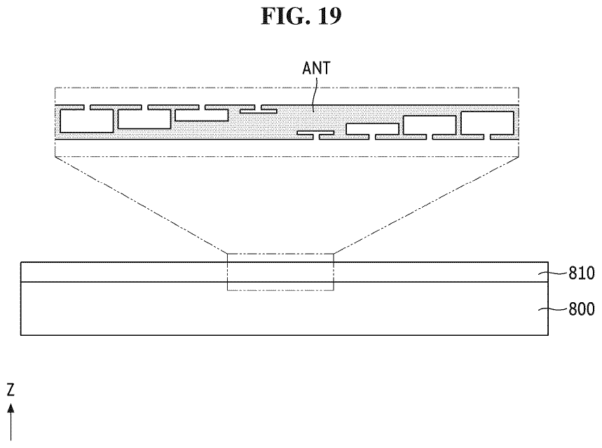

FIG. 19 is a cross-sectional view illustrating a partial layer of a display panel including an antenna illustrated in FIG. 7.

Referring to FIG. 19, the display panel 300 may include an antenna layer including an antenna ANT, and FIG. 19 may be an example illustrating an antenna layer that is a partial layer of the display panel 300.

Referring to FIG. 19, the display panel 300 may include a base layer 800 as an antenna layer, and a first metal layer 810 disposed on the base layer 800.

The base layer 800 is an insulating layer, and may be, for example, a substrate SUB described with reference to FIGS. 3 and 4.

The first metal layer 810 may be a layer on which the antenna ANT of the SSPPs structure described with reference to FIGS. 7 to 11 is formed.

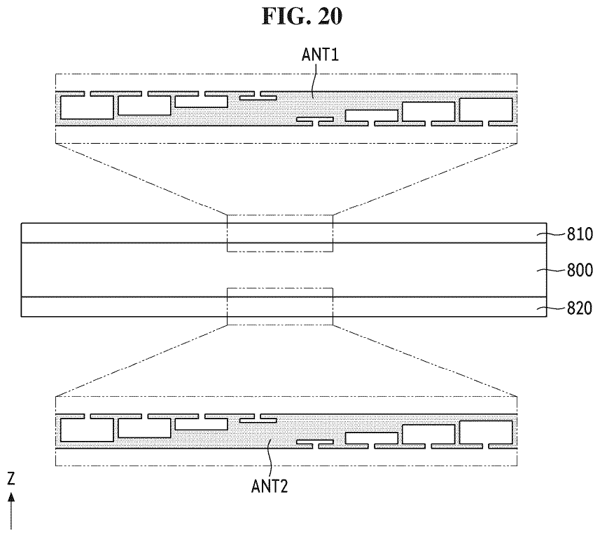

FIG. 20 is a cross-sectional view illustrating a partial layer of a display panel including an antenna according to another embodiment.

The embodiment of FIG. 20 is different from the embodiment of FIG. 19 in that the antenna ANT is configured as a double layer. For example, in the embodiment of FIG. 19, the display panel 300 includes an antenna ANT of a single layer. In some embodiments, in the embodiment of FIG. 20, the display panel 300 may include a double layer including antennas ANT1 and ANT2.

Referring to FIG. 20, the display panel 300 may include a base layer 800 as an antenna layer, a first metal layer 810 disposed above the base layer 800, and a second metal layer 820 disposed below the base layer 800. The base layer 800 is an insulating layer, and may be, for example, a substrate SUB described with reference to FIGS. 3 and 4.

The first metal layer 810 may be a layer of which the first antenna ANT1 of the SSPPs structure described with reference to FIGS. 7 to 11 is formed.

The second metal layer 820 may be a layer of which the second antenna ANT2 of the SSPPs structure described with reference to FIGS. 7 to 11 is formed.

In the antennas ANT1 and ANT2 according to another embodiment illustrated in FIG. 20, electromagnetic field localization capability may be more improved and distributed control capability may be more strengthened such that impedance modulation for radiation may be more efficiently designed than the embodiment of FIG. 19. In some aspects, in the antennas ANT1 and ANT2 according to another embodiment illustrated in FIG. 20, impedance modulation may be performed more easily than the embodiment of FIG. 19, such that a design area of a radiator may be reduced, whereby the antennas ANT1 and ANT2 are easily disposed in the non-display area NDA of the narrow display panel 300.

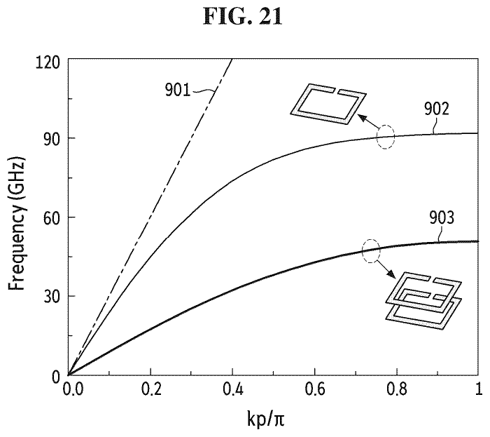

FIG. 21 is a graph illustrating characteristics of the antenna illustrated in FIG. 7 compared with characteristics of the antenna illustrated in FIG. 20.

In FIG. 21, a horizontal axis is a parameter kp/π indicating the phase velocity of the electromagnetic waves, and a vertical axis represents a frequency. A reference numeral 901 illustrated in FIG. 21 represents a ray or a beam. A reference numeral 902 illustrated in FIG. 21 represents a dispersion curve of the antenna ANT illustrated in FIG. 7, and a reference numeral 903 illustrated in FIG. 21 represents a dispersion curve of the antennas ANT1 and ANT2 illustrated in FIG. 20.

Referring to the reference numeral 902 of FIG. 21, it is noted from the dispersion curve of the antenna ANT illustrated in FIG. 7 that the phase velocity of the electromagnetic waves radiated from the antenna ANT at a specific frequency is faster than the phase velocity of the ray or the beam 901.

Referring to the reference numeral 903 of FIG. 21, it is noted from the dispersion curve of the antennas ANT1 and ANT2 illustrated in FIG. 20 that the phase velocity of the electromagnetic waves radiated from the antennas ANT1 and ANT2 at a specific frequency is faster than the phase velocity of the ray or the beam 901. In some aspects, it is noted that the dispersion curve of the antennas ANT1 and ANT2 illustrated in FIG. 20 has a slope lower than a slope of the dispersion curve of the antenna ANT illustrated in FIG. 7 and thus performance of the antennas ANT1 and ANT2 illustrated in FIG. 20 is more excellent than that illustrated in FIG. 7.

Aspects of the present disclosure should not be construed as being limited to the embodiments set forth herein. Rather, the example embodiments are provided such that this disclosure will be thorough and complete and will fully convey the concept of the aspects supported by the present disclosure to those skilled in the art.

While the example aspects supported by the present disclosure has been particularly illustrated and described with reference to embodiments thereof, it will be understood by those of ordinary skill in the art that various changes in form and details may be made therein without departing from the spirit or scope of embodiments supported by the present disclosure as defined by the following claims.

What is claimed is:

1. A display device comprising:
a display panel comprising a display area, a non-display area disposed outside the display area, a protrusion area extended from a portion of the non-display area, and an antenna; and
a circuit board connected to the protrusion area,
wherein the antenna is electrically connected to the circuit board in the protrusion area and comprises:
a first transmission line portion positioned in the protrusion area;
an impedance matching portion disposed in the protrusion area and extended from the first transmission line portion;
a second transmission line portion extended from the impedance matching portion and disposed over a first area of the non-display area corresponding to a corner of the display panel from the protrusion area; and
a radiation pattern portion extended from the second transmission line portion and disposed in a second area of the non-display area corresponding to a side of the display panel, wherein the radiation pattern portion comprises a plurality of radiation slots asymmetrically arranged.

2. The display device of claim 1, wherein the first transmission line portion comprises:
a first power supply line;
a first ground disposed on one side of the first power supply line; and
a second ground disposed on another side of the first power supply line.

3. The display device of claim 2, wherein the impedance matching portion comprises:
a second power supply line extended from the first power supply line and comprising a plurality of matching slots having different respective areas;
a third ground in a form of a quadrant disposed on one side of the second power supply line and extended from the first ground; and
a fourth ground in a form of a quadrant disposed on another side of the second power supply line and extended from the second ground.

4. The display device of claim 3, wherein the third ground and the fourth ground are symmetrical to each other with respect to the second power supply line.

5. The display device of claim 3, wherein the plurality of matching slots comprise:
a first matching slot having a first area;
a second matching slot disposed adjacent to the first matching slot and having a second area larger than the first area;
a third matching slot disposed adjacent to the second matching slot and having a third area larger than the second area;
a fourth matching slot disposed adjacent to the third matching slot and having a fourth area larger than the third area;
a fifth matching slot disposed adjacent to the fourth matching slot and having a fifth area larger than the fourth area; and
a sixth matching slot disposed adjacent to the fifth matching slot and having a sixth area larger than the fifth area.

6. The display device of claim 3, wherein:
the second transmission line portion comprises a third power supply line extended from the second power supply line, and
the third power supply line comprises a plurality of slots each having the same area.

7. The display device of claim 6, wherein a portion of the second transmission line portion is bent toward a lower portion of the display panel at a boundary area between the protrusion area and the non-display area.

8. The display device of claim 6, wherein the radiation pattern portion extends from the third power supply line.

9. The display device of claim 8, wherein:
the plurality of radiation slots comprise:
a first slot unit comprising a first radiation slot, a second radiation slot, a third radiation slot, and a fourth radiation slot having different respective areas; and
a second slot unit comprising a fifth radiation slot, a sixth radiation slot, a seventh radiation slot, and an eighth radiation slot having different respective areas, and
the first slot unit and the second slot unit are alternately disposed along a direction in which the second area of the non-display area extends.

10. The display device of claim 9, wherein an area of the first radiation slot is larger than an area of the second radiation slot,
the area of the second radiation slot is larger than an area of the third radiation slot,
the area of the third radiation slot is larger than an area of the fourth radiation slot,
the area of the fifth radiation slot is smaller than an area of the sixth radiation slot,
the area of the sixth radiation slot is smaller than an area of the seventh radiation slot, and
the area of the seventh radiation slot is smaller than an area of the eighth radiation slot.

11. A mobile electronic device comprising:
a display panel comprising a display area, a non-display area disposed outside the display area, a protrusion area extended from a portion of the non-display area, and an antenna; and
a circuit board connected to the protrusion area,
wherein the antenna is electrically connected to the circuit board in the protrusion area and comprises:
a first transmission line portion positioned in the protrusion area;
an impedance matching portion disposed in the protrusion area and extended from the first transmission line portion;
a second transmission line portion extended from the impedance matching portion and disposed over a first area of the non-display area corresponding to a corner of the display panel from the protrusion area; and
a radiation pattern portion extended from the second transmission line portion and disposed in a second area of the non-display area corresponding to a side of the display panel, wherein the radiation pattern portion comprises a plurality of radiation slots asymmetrically arranged.

12. The mobile electronic device of claim 11, wherein the first transmission line portion comprises:
a first power supply line;
a first ground disposed on one side of the first power supply line; and
a second ground disposed on another side of the first power supply line.

13. The mobile electronic device of claim 12, wherein the impedance matching portion comprises:
a second power supply line extended from the first power supply line and comprising a plurality of matching slots having different respective areas;
a third ground in a form of a quadrant disposed on one side of the second power supply line and extended from the first ground; and
a fourth ground in a form of a quadrant disposed on another side of the second power supply line and extended from the second ground.

14. The mobile electronic device of claim 13, wherein the third ground and the fourth ground are symmetrical to each other with respect to the second power supply line.

15. The mobile electronic device of claim 13, wherein the plurality of matching slots comprise:
a first matching slot having a first area;
a second matching slot disposed adjacent to the first matching slot and having a second area larger than the first area;
a third matching slot disposed adjacent to the second matching slot and having a third area larger than the second area;
a fourth matching slot disposed adjacent to the third matching slot and having a fourth area larger than the third area;
a fifth matching slot disposed adjacent to the fourth matching slot and having a fifth area larger than the fourth area; and
a sixth matching slot disposed adjacent to the fifth matching slot and having a sixth area larger than the fifth area.

16. The mobile electronic device of claim 13, wherein:
the second transmission line portion comprises a third power supply line extended from the second power supply line, and
the third power supply line comprises a plurality of slots each having the same area.

17. The mobile electronic device of claim 16, wherein a portion of the second transmission line portion is bent toward a lower portion of the display panel at a boundary area between the protrusion area and the non-display area.

18. The mobile electronic device of claim 16, wherein the radiation pattern portion extends from the third power supply line.

19. The mobile electronic device of claim 18, wherein:
the plurality of radiation slots comprise:
a first slot unit comprising a first radiation slot, a second radiation slot, a third radiation slot, and a fourth radiation slot having different respective areas; and
a second slot unit comprising a fifth radiation slot, a sixth radiation slot, a seventh radiation slot, and an eighth radiation slot having different respective areas, and
the first slot unit and the second slot unit are alternately disposed along a direction in which the second area of the non-display area extends.

20. The mobile electronic device of claim 19, wherein an area of the first radiation slot is larger than an area of the second radiation slot,
the area of the second radiation slot is larger than an area of the third radiation slot,
the area of the third radiation slot is larger than an area of the fourth radiation slot,
the area of the fifth radiation slot is smaller than an area of the sixth radiation slot,
the area of the sixth radiation slot is smaller than an area of the seventh radiation slot, and
the area of the seventh radiation slot is smaller than an area of the eighth radiation slot.
